(19) United States
(12) Patent Application Publication
(10) Pub. No.: US 2021/0336036 A1
(43) Pub. Date: Oct. 28, 2021

(54) METHOD FOR MANUFACTURING A TOP EMISSION INDIUM GALLIUM ZINC OXIDE THIN FILM TRANSISTOR DEVICE

(71) Applicant: SHENZHEN CHINA STAR OPTOELECTRONICS TECHNOLOGY CO., LTD., Shenzhen, Guangdong (CN)

(72) Inventor: Yanhuan Luo, Shenzhen, Guangdong (CN)

(21) Appl. No.: 16/492,483

(22) PCT Filed: Apr. 26, 2019
(86) PCT No.: PCT/CN2019/084560

§ 371 Date: Sep. 9, 2019

(30) Foreign Application Priority Data
Apr. 4, 2019 (CN) 201910268854.0

(51) Int. Cl. H01L 29/66; H01L 29/786; H01L 21/02

(52) U.S. Cl. CPC H01L 29/66742; H01L 21/02565; H01L 29/7869

(57) ABSTRACT

The present invention discloses a method for manufacturing a top emission indium gallium zinc oxide thin film transistor device, includes a first lithographing step, a second lithographing step, a gate insulation layer forming step, a third lithographing step, a source via hole forming step, an indium gallium zinc oxide active layer exposing step, a source/drain forming step, a planarization layer forming step, a fourth lithographing step, a fifth lithographing step, and a sixth lithographing step. The polyimide electrode barrier spacer is used to manufacture the gate electrode and the source/drain. The polyimide electrode barrier spacers can directly form the source/drain and the gate electrode such that three masks are reduced to be one mask. Moreover, PI can increase density of current of a channel. Accordingly the manufacturing method is simplified and production rate thereof is improved.

### FIELD OF INVENTION

The present invention relates to a method for manufacturing a top emission indium gallium zinc oxide thin film transistor device that employs polyimide (PI) electrode barrier spacer to manufacture gate electrode and source/drain. The source/drain and the gate electrode are formed directly by the PI electrode barrier spacer such that three masks are reduced into one mask. Furthermore, when serving as a gate insulation layer, PI can increase density of current of a channel. Accordingly, the manufacturing method is simplified and production rate thereof is improved.

### BACKGROUND OF INVENTION

Nowadays, active matrix liquid crystal displays (AMLCDs) and active matrix organic light emitting diode (AMOLED) displays because of employing metal oxide thin film transistor (TFT) device including amorphous material of indium gallium zinc oxide (IGZO), have advantages such as ultra-high resolutions, large sizes, high frames, and high transmittance in visible light.

However, the IGZO TFT device has shortages as follows: 1. Usually a gate insulation layer of the IGZO TFT device is made of silicon oxide with a low dielectric constant being primary material, which results in low density of current in the channel, and median with a higher dielectric constant for manufacturing gate insulation layer to increase the density of the current in the channel is required. 2. Manufacture of the IGZO TFT device requires more masks, which disadvantages increase of capacity and yield. Therefore, a method for manufacturing an IGZO TFT device by using reduced masks is required to increase of the capacity and yield.

Furthermore, during the manufacturing of the gate electrode and the source/drain of the top emission gate electrode IGZO TFT device, three masks are needed, which disadvantages increase of capacity and yield. Moreover, the gate insulation layer is generally made of silicon oxide, which results in low density of current in the channel.

Therefore, it is necessary to provide a method for manufacturing a top emission indium gallium zinc oxide thin film transistor device to solve the technical issue of the prior art.

### SUMMARY OF INVENTION

### Technical Issue

Accordingly the present invention provides a method for manufacturing a top emission indium gallium zinc oxide thin film transistor device, the method solves the technical issue that the prior art when requires three masks to manufacture a top emission an gate electrode of an indium gallium zinc oxide (IGZO) thin film transistor (TFT) device and a source/drain, which disadvantages cost reduction and production rate, and the prior art usually employs silicon oxide as material of the gate insulation layer, which results in low density of current in a channel of the device.

### Technical Solution

A main objective of the present invention is to provide a method for manufacturing a top emission indium gallium zinc oxide thin film transistor device, including:

a first lithographing step, comprising developing a first metal layer on a glass substrate, and patterning the first metal layer to form a light shielding layer and a source electrode layer on the first metal layer;

a second lithographing step, comprising depositing a buffer layer and an indium gallium zinc oxide active layer on the glass substrate and stripping the indium gallium zinc oxide active layer off;

a gate insulation layer forming step, comprising depositing a gate insulation layer on the indium gallium zinc oxide active layer, wherein the gate insulation layer entirely covers the indium gallium zinc oxide active layer to isolate the indium gallium zinc oxide active layer;

a third lithographing step, comprising depositing a photoresist on the gate insulation layer, forming a plurality of electrode barrier spacers on the photoresist by a half-tone mask, wherein the electrode barrier spacer is made of polyimide;

a source via hole forming step, comprising removing an exposed portion of the gate insulation layer, a portion of the indium gallium zinc oxide active layer and a portion of the buffer layer to form a source via hole;

an indium gallium zinc oxide active layer exposing step, comprising removing a portion of the photoresist and a portion of the gate insulation layer to expose a portion of the indium gallium zinc oxide active layer on the drain electrode, and finally conductorizing an exposed portion of the indium gallium zinc oxide active layer, wherein a drain disposing hole is defined above the exposed portion;

a source/drain forming step, comprising depositing a second metal layer on the electrode barrier spacers, in the source via hole, and in the drain disposing hole, forming a source electrode portion, a drain electrode portion, and a gate electrode layer on the second metal layer, wherein the source electrode portion is located in the source via hole, the drain electrode portion is located in the drain disposing hole, and the gate electrode layer is located on the electrode barrier spacers; and

a planarization layer forming step, comprising depositing a passivation layer on the second metal layer, and depositing a planarization layer on the passivation layer.

In an embodiment of the present invention, the method further comprises a fourth lithographing step, comprising removing a portion of the planarization layer and a portion of the passivation layer to form an anode via hole.

In an embodiment of the present invention, the method further comprises a fifth lithographing step, comprising depositing an anode layer on the planarization layer with a portion of the anode layer disposed in the anode via hole, and forming a pixel electrode on the anode layer.

In an embodiment of the present invention, the method further comprises sixth lithographing step the method further comprises a sixth lithographing step, comprising depositing a pixel definition layer on the planarization layer, and forming a pixel pattern on the pixel definition layer.

In an embodiment of the present invention, in the second lithographing step, the indium gallium zinc oxide active layer is formed by an exposing process, a development process, and a wet engraving process.

In an embodiment of the present invention, in the source via hole forming step, the exposed portion of the gate insulation layer, the portion of the indium gallium zinc oxide active layer, and the portion of the buffer layer are removed by a dry engraving process, a wet engraving process, and a dry engraving process respectively.

In an embodiment of the present invention, in the fourth lithographing step, the anode via hole is defined by a development process removing a portion of the planarization layer and by a dry engraving process removing a portion of the passivation layer.

In an embodiment of the present invention, in the fifth lithographing step, the pixel electrode is formed on the anode layer by a gluing process, an exposing process, a development process, an etching process, and a stripping process.

In an embodiment of the present invention, in the sixth lithographing step, the pixel pattern is formed on the pixel definition layer by a development process.

In an embodiment of the present invention, the photoresist is negative photosensitive glue.

Another objective of the present invention is to provide a method for manufacturing a top emission indium gallium zinc oxide thin film transistor device, including:

a first lithographing step, comprising developing a first metal layer on a glass substrate, and patterning the first metal layer to form a light shielding layer and a source electrode layer on the first metal layer;

a second lithographing step, comprising depositing a buffer layer and an indium gallium zinc oxide active layer on the glass substrate and stripping the indium gallium zinc oxide active layer off;

a gate insulation layer forming step, comprising depositing a gate insulation layer on the indium gallium zinc oxide active layer, wherein the gate insulation layer entirely covers the indium gallium zinc oxide active layer to isolate the indium gallium zinc oxide active layer;

a third lithographing step, comprising depositing a photoresist on the gate insulation layer, forming a plurality of electrode barrier spacers on the photoresist by a half-tone mask, wherein the electrode barrier spacer is made of polyimide;

a source via hole forming step, comprising removing an exposed portion of the gate insulation layer, a portion of the indium gallium zinc oxide active layer and a portion of the buffer layer to form a source via hole;

an indium gallium zinc oxide active layer exposing step, comprising removing a portion of the photoresist and a portion of the gate insulation layer to expose a portion of the indium gallium zinc oxide active layer on the drain electrode, and finally conductorizing an exposed portion of the indium gallium zinc oxide active layer, wherein a drain disposing hole is defined above the exposed portion;

a source/drain forming step, comprising depositing a second metal layer on the electrode barrier spacers, in the source via hole, and in the drain disposing hole, forming a source electrode portion, a drain electrode portion, and a gate electrode layer on the second metal layer, wherein the source electrode portion is located in the source via hole, the drain electrode portion is located in the drain disposing hole, and the gate electrode layer is located on the electrode barrier spacers; and

a planarization layer forming step, comprising depositing a passivation layer on the second metal layer, and depositing a planarization layer on the passivation layer;

wherein the method further comprises a fourth lithographing step, comprising removing a portion of the planarization layer and a portion of the passivation layer to form an anode via hole;

wherein the method further comprises a fifth lithographing step, comprising depositing an anode layer on the planarization layer with a portion of the anode layer disposed in the anode via hole, and forming a pixel electrode on the anode layer;

wherein the method further comprises a sixth lithographing step, comprising depositing a pixel definition layer on the planarization layer, and forming a pixel pattern on the pixel definition layer;

wherein in the second lithographing step, the indium gallium zinc oxide active layer is formed by an exposing process, a development process, and a wet engraving process;

wherein in the source via hole forming step, the exposed portion of the gate insulation layer, the portion of the indium gallium zinc oxide active layer, and the portion of the buffer layer are removed by a dry engraving process, a wet engraving process, and a dry engraving process respectively; and

wherein in the fourth lithographing step, the anode via hole is defined by a development process removing a portion of the planarization layer and by a dry engraving process removing a portion of the passivation layer.

In an embodiment of the present invention, in the fifth lithographing step, the pixel electrode is formed on the anode layer by a gluing process, an exposing process, a development process, an etching process, and a stripping process.

In an embodiment of the present invention, in the sixth lithographing step, the pixel pattern is formed on the pixel definition layer by a development process.

In an embodiment of the present invention, the photoresist is negative photosensitive glue.

### Advantages

Compared to the prior art, the present invention forms the polyimide (PI) electrode barrier spacer by the third lithographing step (third mask), and uses the PI electrode barrier spacers as a substrate to simultaneously the gate electrode and the source/drain in the source/drain forming step. The PI electrode barrier spacers can directly form the source/drain and the gate electrode such that three masks are reduced to be one mask. Moreover, PI can increase density of current of a channel. Accordingly the manufacturing method is simplified and production rate thereof is improved.

In order to make the above contents of the present invention clearer and more understandable, detailed descriptions of preferred embodiments in conjunction with the drawings will be presented as follows.

### DESCRIPTION OF DRAWINGS

FIGS. 1A and 1B are flowcharts of a method for manufacturing a top emission indium gallium zinc oxide thin film transistor device of the present invention.

FIG. 2 is a cross-sectional side view of a semi-finished product of a thin film transistor device corresponding to a first lithographing step of the method of the present invention.

FIG. 3 is a cross-sectional side view of a semi-finished product of a thin film transistor device corresponding to a second lithographing step of the method of the present invention.

FIG. 4 is a cross-sectional side view of a semi-finished product of a thin film transistor device corresponding to a gate insulation layer forming step of the method of the present invention.

FIG. 5 is a cross-sectional side view of a semi-finished product of a thin film transistor device corresponding to a third lithographing step of the method of the present invention.

FIG. 6 is a cross-sectional side view of a semi-finished product of a thin film transistor device corresponding to a source via hole forming step of the method of the present invention.

FIG. 7 is a cross-sectional side view of a semi-finished product of a thin film transistor device corresponding to an indium gallium zinc oxide active layer exposing step of the method of the present invention.

FIG. 8 is a cross-sectional side view of a semi-finished product of a thin film transistor device corresponding to a source/drain forming step of the method of the present invention.

FIG. 9 is a cross-sectional side view of a semi-finished product of a thin film transistor device corresponding to a planarization layer forming step of the method of the present invention.

FIG. 10 is a cross-sectional side view of a semi-finished product of a thin film transistor device corresponding to a fourth lithographing step of the method of the present invention.

FIG. 11 is a cross-sectional side view of a semi-finished product of a thin film transistor device corresponding to a fifth lithographing step of the method of the present invention.

FIG. 12 is a cross-sectional side view of a finished product of a thin film transistor device corresponding to a sixth lithographing step of the method of the present invention.

### DETAILED DESCRIPTION OF PREFERRED EMBODIMENTS

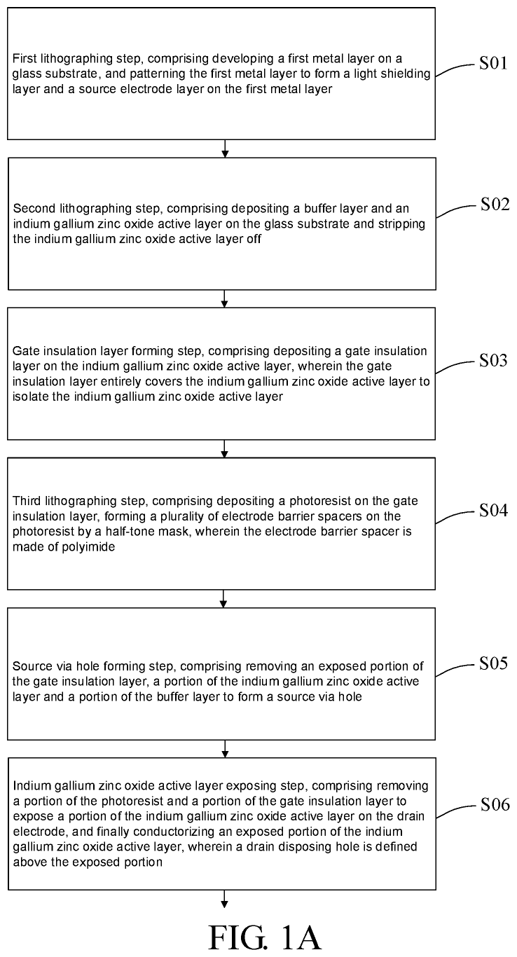

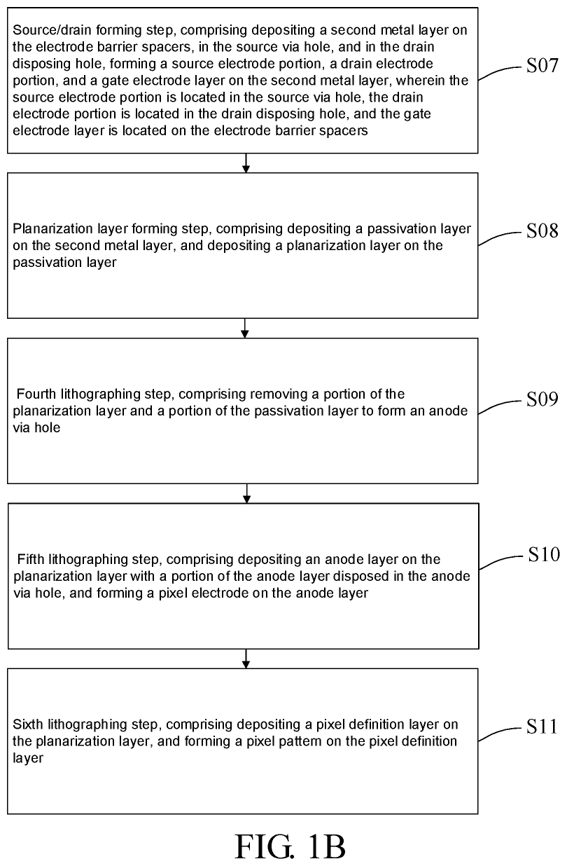

With reference to FIGS. 1A and 1B, a method for manufacturing a top emission indium gallium zinc oxide thin film transistor device of the present invention includes: a first lithographing step S01, a second lithographing step S02, a gate insulation layer forming step S03, a third lithographing step S04, source via hole forming step S05, an indium gallium zinc oxide active layer exposing step S06, a source/drain forming step S07, a planarization layer forming step S08, a fourth lithographing step S09, a fifth lithographing step S10, and a sixth lithographing step S11.

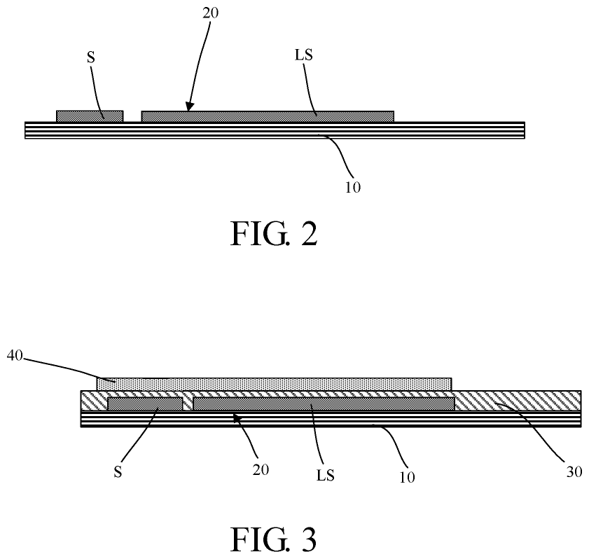

With reference to FIG. 2, the first lithographing step (Photo Engraving Process, PEP) S01 (a first mask is used), includes depositing a first metal layer 20 on a glass substrate 10, and patterning the first metal layer 20 to a light shielding layer LS and a source electrode layer S form on the first metal layer 20.

With reference to FIG. 3, the second lithographing step S02 (a second mask is used), includes depositing a buffer layer 30 and an indium gallium zinc oxide (IGZO) active layer 40 on the glass substrate 10, and stripping the IGZO active layer 40 off. In an embodiment of the present invention, in the second lithographing step S02, the IGZO active layer 40 is formed by an exposing process, a development process, and a wet engraving process.

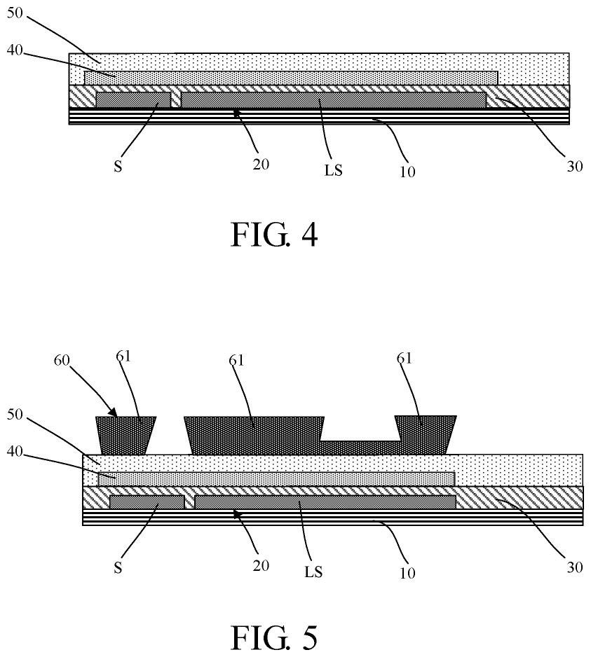

With reference to FIG. 4, the gate insulation layer forming step S03, includes depositing an gate insulation layer 50 on the IGZO active layer 40. The gate insulation layer 50 entirely covers the IGZO active layer 40 to isolate the IGZO active layer 40.

With reference to FIG. 5, the third lithographing step S04 (a third mask is used), includes depositing a photoresist 60 on the gate insulation layer 50, and forming [symbol] the photoresist 60 a plurality of electrode barrier spacers 61 by a half-tone mask. The electrode barrier spacers 61 are made of polyimide. In an embodiment of the present invention, the photoresist 60 is negative photosensitive glue.

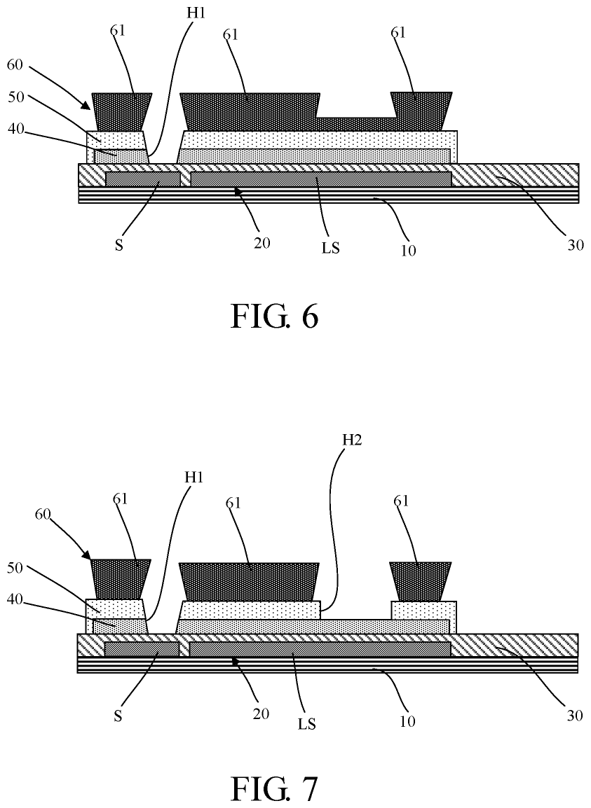

With reference to FIG. 6, the source via hole forming step S05, includes removing an exposed portion of the gate insulation layer 50, a portion of the IGZO active layer 40, and a portion of the buffer layer 30 to form a source via hole H1. In an embodiment of the present invention, in the source via hole forming step S05, the exposed portion of the gate insulation layer 50, the portion of the IGZO active layer 40, and the portion of the buffer layer 30 are removed by a dry engraving process, a wet engraving process, and a dry engraving process respectively.

With reference to FIG. 7, the indium gallium zinc oxide active layer exposing step S06, includes removing a portion of the photoresist 60 and a portion of the gate insulation layer 50 to expose a portion of the IGZO active layer 40 on the drain electrode, and finally conductorizing the exposed portion (the portion exposed) of the IGZO active layer 40. A drain disposing hole H2 is defined above the exposed portion.

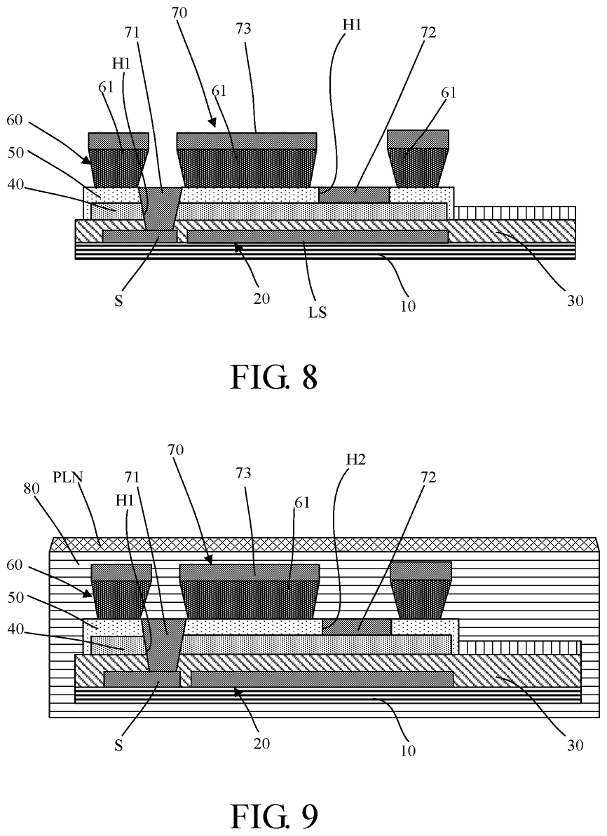

With reference to FIG. 8, the source/drain forming step S07, includes depositing a second metal layer 70 on the electrode barrier spacers 61, in the source via hole H1, and in the drain disposing hole H2, forming a source electrode portion 71 on the second metal layer 70 and located in the source via hole H1, forming a drain electrode portion 72 in the drain disposing hole H2, and forming a gate electrode layer 73 on the electrode barrier spacers 61.

With reference to FIG. 9, the planarization layer forming step S08, includes depositing a passivation layer 80 on the second metal layer 70, and depositing a planarization layer PLN on the passivation layer 80.

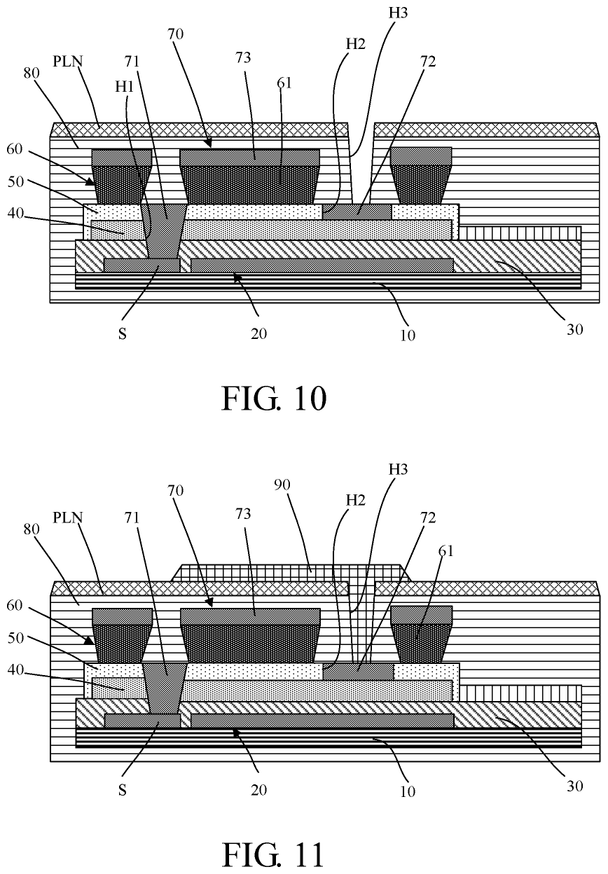

With reference to FIG. 10, the fourth lithographing step S09 (a fourth mask is used), includes removing a portion of the planarization layer PLN and a portion of the passivation layer 80 to form an anode via hole H3. In an embodiment of the present invention, in the fourth lithographing step S09, the portion of the planarization layer PLN is removed by a development process, and the portion of the passivation layer 80 is removed by a dry engraving process to form the anode via hole H3.

With reference to FIG. 11, the fifth lithographing step S10 (a fifth mask is used), includes depositing anode layer 90 on the planarization layer PLN with a portion of the anode layer 90 disposed in the anode via hole H3, and then forming a pixel electrode on the anode layer 90. In an embodiment of the present invention, in the fifth lithographing step S10, the pixel electrode is formed on the anode layer 90 by a gluing process, an exposing process, a development process, an etching process, and a stripping process.

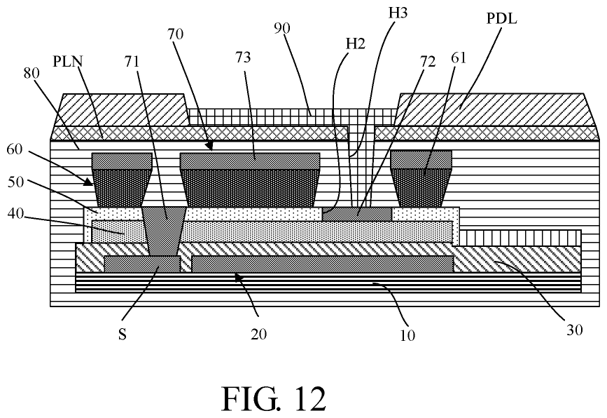

With reference to FIG. 12, the sixth lithographing step S11 (a sixth mask is used), includes depositing a pixel definition layer PDL on the planarization layer PLN, and forming a pixel pattern on the pixel definition layer PDL. In an embodiment of the present invention, in the sixth lithographing step S11, the pixel pattern is formed on the pixel definition layer PDL by a development process.

Compared to the prior art, forms the polyimide (PI) electrode barrier spacer 61 by the third lithographing step S04, and uses the PI electrode barrier spacers 61 as a substrate to simultaneously the gate electrode and the source/drain in the source/drain forming step S07. The PI electrode barrier spacers 61 can directly form the source/drain and the gate electrode such that three masks are reduced to be one mask. Moreover, PI serving as the gate insulation layer 50 can increase density of current of a channel. Accordingly the manufacturing method is simplified and production rate thereof is improved.

What is claimed is:

1. A method for manufacturing a top emission indium gallium zinc oxide thin film transistor device, comprising:
a first lithographing step, comprising developing a first metal layer on a glass substrate, and patterning the first metal layer to form a light shielding layer and a source electrode layer on the first metal layer;
a second lithographing step, comprising depositing a buffer layer and an indium gallium zinc oxide active layer on the glass substrate and stripping the indium gallium zinc oxide active layer off;
a gate insulation layer forming step, comprising depositing a gate insulation layer on the indium gallium zinc oxide active layer, wherein the gate insulation layer entirely covers the indium gallium zinc oxide active layer to isolate the indium gallium zinc oxide active layer;
a third lithographing step, comprising depositing a photoresist on the gate insulation layer, forming a plurality of electrode barrier spacers on the photoresist by a half-tone mask, wherein the electrode barrier spacer is made of polyimide;
a source via hole forming step, comprising removing an exposed portion of the gate insulation layer, a portion of the indium gallium zinc oxide active layer and a portion of the buffer layer to form a source via hole;
an indium gallium zinc oxide active layer exposing step, comprising removing a portion of the photoresist and a portion of the gate insulation layer to expose a portion of the indium gallium zinc oxide active layer on the drain electrode, and finally conductorizing an exposed portion of the indium gallium zinc oxide active layer, wherein a drain disposing hole is defined above the exposed portion;
a source/drain forming step, comprising depositing a second metal layer on the electrode barrier spacers, in the source via hole, and in the drain disposing hole, forming a source electrode portion, a drain electrode portion, and a gate electrode layer on the second metal layer, wherein the source electrode portion is located in the source via hole, the drain electrode portion is located in the drain disposing hole, and the gate electrode layer is located on the electrode barrier spacers; and
a planarization layer forming step, comprising depositing a passivation layer on the second metal layer, and depositing a planarization layer on the passivation layer.

2. The method for manufacturing a top emission indium gallium zinc oxide thin film transistor device as claimed in claim 1, wherein the method further comprises a fourth lithographing step, comprising removing a portion of the planarization layer and a portion of the passivation layer to form an anode via hole.

3. The method for manufacturing a top emission indium gallium zinc oxide thin film transistor device as claimed in claim 2, wherein the method further comprises a fifth lithographing step, comprising depositing an anode layer on the planarization layer with a portion of the anode layer disposed in the anode via hole, and forming a pixel electrode on the anode layer.

4. The method for manufacturing a top emission indium gallium zinc oxide thin film transistor device as claimed in claim 3, wherein the method further comprises a sixth lithographing step, comprising depositing a pixel definition layer on the planarization layer, and forming a pixel pattern on the pixel definition layer.

5. The method for manufacturing a top emission indium gallium zinc oxide thin film transistor device as claimed in claim 4, wherein in the second lithographing step, the indium gallium zinc oxide active layer is formed by an exposing process, a development process, and a wet engraving process.

6. The method for manufacturing a top emission indium gallium zinc oxide thin film transistor device as claimed in claim 4, wherein in the source via hole forming step, the exposed portion of the gate insulation layer, the portion of the indium gallium zinc oxide active layer, and the portion of the buffer layer are removed by a dry engraving process, a wet engraving process, and a dry engraving process respectively.

7. The method for manufacturing a top emission indium gallium zinc oxide thin film transistor device as claimed in claim 4, wherein in the fourth lithographing step, the anode via hole is defined by a development process removing a portion of the planarization layer and by a dry engraving process removing a portion of the passivation layer.

8. The method for manufacturing a top emission indium gallium zinc oxide thin film transistor device as claimed in claim 4, wherein in the fifth lithographing step, the pixel electrode is formed on the anode layer by a gluing process, an exposing process, a development process, an etching process, and a stripping process.

9. The method for manufacturing a top emission indium gallium zinc oxide thin film transistor device as claimed in claim 4, wherein in the sixth lithographing step, the pixel pattern is formed on the pixel definition layer by a development process.

10. The method for manufacturing a top emission indium gallium zinc oxide thin film transistor device as claimed in claim 4, wherein the photoresist is a negative photosensitive glue.

11. A method for manufacturing a top emission indium gallium zinc oxide thin film transistor device, comprising:
a first lithographing step, comprising developing a first metal layer on a glass substrate, and patterning the first metal layer to form a light shielding layer and a source electrode layer on the first metal layer;
a second lithographing step, comprising depositing a buffer layer and an indium gallium zinc oxide active layer on the glass substrate and stripping the indium gallium zinc oxide active layer off;
a gate insulation layer forming step, comprising depositing a gate insulation layer on the indium gallium zinc oxide active layer, wherein the gate insulation layer entirely covers the indium gallium zinc oxide active layer to isolate the indium gallium zinc oxide active layer;
a third lithographing step, comprising depositing a photoresist on the gate insulation layer, forming a plurality of electrode barrier spacers on the photoresist by a half-tone mask, wherein the electrode barrier spacer is made of polyimide;
a source via hole forming step, comprising removing an exposed portion of the gate insulation layer, a portion of the indium gallium zinc oxide active layer and a portion of the buffer layer to form a source via hole;
an indium gallium zinc oxide active layer exposing step, comprising removing a portion of the photoresist and a portion of the gate insulation layer to expose a portion of the indium gallium zinc oxide active layer on the drain electrode, and finally conductorizing an exposed portion of the indium gallium zinc oxide active layer, wherein a drain disposing hole is defined above the exposed portion;
a source/drain forming step, comprising depositing a second metal layer on the electrode barrier spacers, in the source via hole, and in the drain disposing hole, forming a source electrode portion, a drain electrode portion, and a gate electrode layer on the second metal layer, wherein the source electrode portion is located in the source via hole, the drain electrode portion is located in the drain disposing hole, and the gate electrode layer is located on the electrode barrier spacers; and
a planarization layer forming step, comprising depositing a passivation layer on the second metal layer, and depositing a planarization layer on the passivation layer;
wherein the method further comprises a fourth lithographing step, comprising removing a portion of the planarization layer and a portion of the passivation layer to form an anode via hole;
wherein the method further comprises a fifth lithographing step, comprising depositing an anode layer on the planarization layer with a portion of the anode layer disposed in the anode via hole, and forming a pixel electrode on the anode layer;
wherein the method further comprises a sixth lithographing step, comprising depositing a pixel definition layer on the planarization layer, and forming a pixel pattern on the pixel definition layer;
wherein in the second lithographing step, the indium gallium zinc oxide active layer is formed by an exposing process, a development process, and a wet engraving process;
wherein in the source via hole forming step, the exposed portion of the gate insulation layer, the portion of the indium gallium zinc oxide active layer, and the portion of the buffer layer are removed by a dry engraving process, a wet engraving process, and a dry engraving process respectively; and
wherein in the fourth lithographing step, the anode via hole is defined by a development process removing a portion of the planarization layer and by a dry engraving process removing a portion of the passivation layer.

12. The method for manufacturing a top emission indium gallium zinc oxide thin film transistor device as claimed in claim 11, wherein in the fifth lithographing step, the pixel electrode is formed on the anode layer by a gluing process, an exposing process, a development process, an etching process, and a stripping process.

13. The method for manufacturing a top emission indium gallium zinc oxide thin film transistor device as claimed in claim 11, wherein in the sixth lithographing step, the pixel pattern is formed on the pixel definition layer by a development process.

14. The method for manufacturing a top emission indium gallium zinc oxide thin film transistor device as claimed in claim 11, wherein the photoresist is a negative photosensitive glue.
